(19) United States
(12) Patent Application Publication
(10) Pub. No.: US 2026/0182459 A1
(43) Pub. Date: Jun. 25, 2026

(54) METHODS FOR MAINTAINING STABLE HIGH RESISTIVITY OF SOI WAFERS

(71) Applicant: Murata Manufacturing Co., Ltd., Nagaokakyo-Shi, Kyoto (JP)

(72) Inventors: Kouassi Sebastien KOUASSI, SAN DIEGO, CA (US); Ahmed MAGHAWRI, SAN DIEGO, CA (US); Wen Hao WANG, SAN DIEGO, CA (US); Richard DOWLING, SAN DIEGO, CA (US); Michael MERCADO, SAN DIEGO, CA (US)

(21) Appl. No.: 19/126,980

(22) PCT Filed: Nov. 2, 2023
(86) PCT No.: PCT/US2023/078537

§ 371 Date: May 2, 2025

Related U.S. Application Data
(60) Provisional application No. 63/382,439, filed on Nov. 4, 2022.

(51) Int. Cl. H10W 90/00; H10D 86/00; H10P 36/20; H10W 72/29

(52) U.S. Cl. CPC H10W 90/00; H10D 86/201; H10P 36/20; H10W 72/29

(57) ABSTRACT

Methods for maintaining stable resistivity of a high resistivity silicon-on-insulator (HR-SOI) wafer are presented. The HR-SOI wafer includes a HR-Si substrate having a resistivity that is higher than about 1000 ohm. cm and a dopant concentration that is smaller than about 10¹³×cm-³. Packaging processing steps of the HR-SOI wafer are performed at a peak temperature that is below about 250 degrees centigrade. According to one aspect, a polyimidization processing step according to the present disclosure is performed at a peak temperature that is below about 250 degrees centigrade. According to another aspect, the packaging processing steps do not include the polyimidization processing step.

### CROSS-REFERENCE TO RELATED APPLICATIONS

The present application claims priority to U.S. Provisional Application No. 62/382,439 filed on Nov. 4, 2022, for “METHODS FOR MAINTAINING STABLE HIGH RESISTIVITY OF SOI WAFERS”, the content of which is incorporated herein by reference in its entirety.

### FIELD

The present disclosure is related to semiconductor technology, and more particularly to methods for maintaining a desired high resistivity of a silicon-on-insulator (SOI) wafer throughout fabrication and packaging steps of integrated circuits on the SOI wafer.

### BACKGROUND

FIG. 1A shows a cross-sectional view of a (high resistivity) SOI wafer (100A, HR-SOI, also known as a wafer) that includes a high-resistivity (silicon) substrate (150) over which a thin layer of silicon (Si, 110, also referred to as SOI layer) overlying an insulating BOX layer (120, e.g., SiO₂, buried oxide layer) is formed. Circuits (also known as SOI circuits) that include devices (e.g., SOI transistors) may be formed/fabricated in and above the thin layer of silicon (110) by methods and techniques that are well-known in the art. In case where such circuits are intended to operate, or include devices that operate, at high frequencies, such as in RF applications, substantial benefits can be obtained by adopting a high-resistivity bulk silicon substrate (150, HR-Si) as shown in FIG. 1A.

In some cases, performance of RF devices fabricated on the HR-SOI wafer (100A) may be affected by the well-known in the art parasitic surface conduction (PSC) effect at the interface between the BOX layer (120) and the bulk substrate (150) that is due to the capacitor-like configuration a SOI stack creates. As known to a person skilled in the art, PSC may be due to fixed positive charges within the BOX layer (120) near the interface with the bulk substrate (150) attracting free (charge) carriers and thereby reducing effective resistivity of the bulk substrate (150) and resulting in increased loss and nonlinearity. Provision of a trap-rich layer (130) between the BOX layer and the (HR-Si) bulk substrate (150) as shown in the cross-sectional view of the SOI substrate (100B) of FIG. 1B may reduce the PSC effect and therefore increase performance of the RF devices. As known to a person skilled in the art, presence of the trap-rich layer (130) may produce a trap-rich effect that includes trapping of free charges (e.g., electrons, carriers) underneath the BOX layer (120), thereby preventing flow of current, e.g., due to PSC, that may produce undesired coupling of signals to/between the RF devices formed in the thin layer of silicon (110).

Once fabricated on the HR-SOI wafer (100A or 100B), the fabricated circuits may be packaged into individual packages (ICs) by methods and techniques that are also well-known in the art. During the fabrication and packaging, the HR-SOI wafer (100A or 100B) may be subjected to various processing steps requiring different temperatures or temperature ranges, from lower temperatures in the few hundred degrees centigrade, to higher temperatures that may reach or surpass thousand degrees centigrade. Some of these temperatures may affect the HR-SOI wafer in ways that may modify/alter a nominal high resistivity value of the HR-Si substrate (150).

It is desired that throughout the above-described processing steps, spanning from fabrication to packaging, the HR-Si substrate (150) maintains its nominal high resistivity value so to guarantee RF performance of the fabricated/packaged devices/circuits. Teachings according to the present disclosure describe methods for maintaining such high resistivity.

### SUMMARY

According to a first aspect of the present disclosure, a method for processing a high resistivity silicon-on-insulator (HR-SOI) wafer is presented, the method comprising: processing, via semiconductor fabrication steps, the HR-SOI wafer, thereby producing: a circuit layer atop a silicon-on-insulator (SOI) layer of the HR-SOI wafer; and a passivation layer atop the circuit layer including an opening that exposes a metal pad in contact with the circuit layer; overlying a polyimide atop the passivation layer and the metal pad; and curing the polyimide at a peak temperature that is below about 250 degrees centigrade thereby maintaining a nominal high resistivity of the HR-SOI wafer.

According to a second aspect of the present disclosure, a method for processing a high resistivity silicon-on-insulator (HR-SOI) wafer is presented, the method comprising: processing, via semiconductor fabrication steps, the HR-SOI wafer, thereby producing a circuit layer comprising integrated circuits; and processing, via integrated circuit packaging steps, the HR-SOI wafer, thereby producing packaged integrated circuits, wherein a peak temperature during the integrated circuit packaging steps is below about 250 degrees centigrade thereby maintaining a nominal high resistivity of the HR-SOI wafer.

According to a third aspect of the present disclosure, a method for processing a high resistivity silicon-on-insulator (HR-SOI) wafer is presented, the method comprising: processing, via semiconductor fabrication steps, the HR-SOI wafer, thereby producing a circuit layer comprising integrated circuits; and processing, via integrated circuit packaging steps, the HR-SOI wafer, thereby producing packaged integrated circuits, wherein the integrated circuit packaging steps include a polyimidization step.

According to a fourth aspect of the present disclosure, a method for processing a high resistivity silicon-on-insulator (HR-SOI) wafer is presented, the method comprising: processing, via semiconductor fabrication steps, the HR-SOI wafer, thereby producing: a circuit layer atop a silicon-on-insulator (SOI) layer of the HR-SOI wafer; and a passivation layer atop the circuit layer including an opening that exposes a metal pad in contact with the circuit layer; overlying a polyimide atop the passivation layer and the metal pad; and curing the polyimide at a peak temperature selected such that a nominal high resistivity of the HR-SOI wafer is maintained.

Further aspects of the disclosure are provided in the description, drawings and claims of the present application.

### BRIEF DESCRIPTION OF THE DRAWINGS

The accompanying drawings, which are incorporated into and constitute a part of this specification, illustrate one or more embodiments of the present disclosure and, together with the description of example embodiments, serve to explain the principles and implementations of the disclosure.

FIG. 1A shows a cross-sectional view of a silicon-on-insulator (SOI) substrate including a high resistivity silicon substrate.

FIG. 1B shows a cross-sectional view of silicon-on-insulator (SOI) substrate including a high resistivity silicon substrate and a trap-rich layer.

FIG. 2 shows graphs representative of resistivity as function of depth in the SOI substrate of FIG. 1B.

FIG. 3 shows graphs representative of resistivity as function of depth in the SOI substrate of FIG. 1B subsequent to a processing step.

FIG. 4 shows various processing steps of a SOI substrate according to an embodiment of the present disclosure.

FIG. 5 shows various processing steps of a SOI substrate according to another embodiment of the present disclosure.

Like reference numbers and designations in the various drawings indicate like elements.

### DETAILED DESCRIPTION

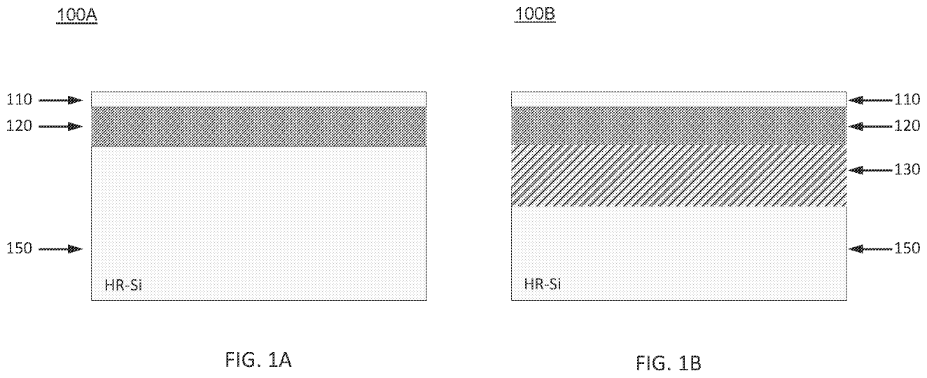

The high resistivity (bulk) silicon (HR-Si) substrate (150) shown in FIG. 1A/1B may be fabricated with an intended/nominal resistivity that when used in the high resistivity SOI (HR-SOI) wafers (100A or 100B) may provide RF performance advantages as known in the art.

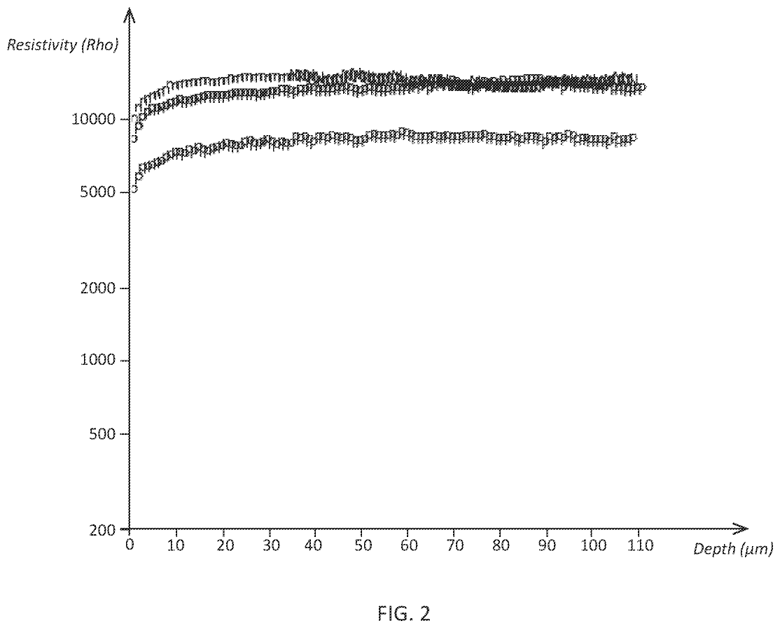

FIG. 2 shows (three) exemplary graphs representative of resistivity (Rho, measured in units of ohm·cm) as function of depth measured from the surface of the HR Si substrate in a HR-SOI wafer, such as, for example, the HR-SOI wafer (100B) of a FIG. 1B. In such graphs, the value zero (shown as 0 in FIG. 2) of the depth represents the bottom surface of the layer (120, BOX layer) and greater values of the depth represent greater distances from the bottom surface of the layer (120) into the HR-SOI wafer. Accordingly, considering the HR-SOI wafer (100B) of FIG. 1B, a corresponding resistivity graph may include resistivity of the layer (130) that is arranged between the layers (150) and (120). FIG. 2 shows resistivity graphs for (three) exemplary HR-SOI wafers.

As shown in FIG. 2, at any depth inside of the HR-SOI, the resistivity of the HR-SOI is in a range from about 5000 ohm·cm to 10000 ohm·cm or larger. Notably, as shown in FIG. 2, at depths greater than about 10 μm, the resistivity profile is substantially flat, or in other words, the resistivity is substantially constant at depths greater than about 10 μm. It is noted that the initial slopes in the resistivity graphs shown in FIG. 2 may be attributed to presence of the layer (130) shown in FIG. 1B that may extend few micrometers (μm) in depth. Accordingly, the substantially flat resistivity profiles at depths greater than about 10 μm shown in FIG. 2 may correspond to resistivity profiles of respective HR-Si substrates (e.g., 150 of FIG. 1B). Similar flat profiles in a region of the HR-Si substrate (150) of FIG. 1A is expected.

As used herein, a high-resistivity silicon (HR-Si) substrate is a silicon substrate with a resistivity of about 1000 ohm·cm or higher. In other words, as shown in FIG. 2, at any depth of the HR-Si substrate, the resistivity of the HR-Si substrate in the sense of the present disclosure is greater than about 1000 ohm·cm.

It is noted that a resistivity of a silicon substrate may be impacted by a concentration of dopants (e.g., carriers) in the material (silicon) of the substrate. For non-HR-Si substrates, typical values of dopant concentration are greater than (e.g., about, or same order of magnitude) 10¹⁴×cm⁻³, such as in in a range from 10¹⁴×cm⁻³ to 10¹⁵×cm⁻³ or higher. For example, a p-type non-HR-Si substrate may have a concentration of p-type dopants in a range from (e.g., about, or same order of magnitude) 10¹⁴×cm⁻³ to 10¹⁸×cm⁻³ or higher. On the other hand, a concentration of dopants for a HR-Si substrate in the sense of the present disclosure is smaller than (e.g., about, or same order of magnitude) 10¹³×cm⁻³, with values in a range from 10¹²×cm⁻³ to 10¹³×cm⁻³. In other words, dopant concentration of a HR-Si substrate as referred in the present disclosure is two or more orders of magnitude smaller than that of (typical) non-HR-Si substrates.

It should be noted that such low levels of doping of silicon (i.e., in a range from 10¹²×cm⁻³ to 10¹³×cm⁻³) in order to provide substrate resistivities that are (e.g., about) 1000 ohm·cm or higher have only become feasible with recent material fabrication techniques and processes. Therefore, and as will be further described in the present disclosure, problems solved by the present teachings may be considered relevant (e.g., detectable) only in the context of processing of a HR-SOI wafer.

In particular, feasibility of a HR-Si substrate in the sense of the present disclosure may be based on availability of silicon material that includes a low concentration of oxygen atoms, also known as interstitial oxygen (Oi), in a lattice of the silicon material. This is because Oi may behave like a dopant when/if it is electrically activated, as will be described in the below, and hence its low concentration may be desirable. In other words, availability of a silicon material with low concentration of oxygen (e.g., Oi) may be considered as one desirable condition for provision of a HR-Si substrate in the sense of the present disclosure.

Applicant notes that present/recent material fabrication techniques and processes may allow reduction of oxygen atom concentration that is inherently present in a silicon material (e.g., SiO2) to lower values than those achievable in the past (e.g., greater than 10¹⁸×cm⁻³). Such lower values may be as low as about (e.g., same order of magnitude) 10¹¹×cm⁻³, with typical lower values in a range from about 10¹¹×cm⁻³ to 10¹²×cm⁻³.

As used herein, a low-oxygen silicon material is a silicon material with a concentration of oxygen (e.g., Oi) that is lower than (e.g., about, or same order of magnitude) 10¹⁵×cm⁻³, such as, for example, in a range from about (e.g., same order of magnitude) 10¹¹×cm⁻³ to lower than 10¹⁵×cm⁻³. As used herein, a high-oxygen silicon material is a silicon material with a concentration of oxygen (e.g., Oi) that is greater than 10¹⁵×cm⁻³, such as, for example, in a range from about (e.g., same order of magnitude) 10¹⁸×cm⁻³ to 10²⁰×cm⁻³.

As measured in units of old-ppma (e.g., oppma, old part per million according to ASTM standard), such values of the concentration of oxygen for a low-oxygen silicon material may translate to be below about 15. This is in contrast to high-oxygen silicon material having oxygen concentrations in a range above about 15 old ppma. Accordingly, oxygen concentration of silicon substrate made from a low-oxygen silicon material is below about 15 oppma at any depth of the substrate, and oxygen concentration of silicon substrate made from a high-oxygen silicon material is above about 15 oppma at any depth of the substrate.

HR-Si substrates and non-HR-Si substrates may use either a low-oxygen or high-oxygen silicon material. Teachings according to the present disclosure relate to HR-Si substrates in the sense of the present disclosure that are made with low-oxygen silicon material. Present day non-HR-Si substrates may be made with low-oxygen silicon material as well.

Because the oxygen interstitials (Oi) in a HR-Si substrate are not electrically active, they may not, for example, influence performance of a circuit fabricated on such substrate while operating under normal (lower) temperatures (e.g., about 150 degrees centigrade or lower), including RF performance of the circuit as related to a resistivity of the substrate. In other words, presence of the oxygen atoms in the HR-Si substrate may not be regarded as an issue so long as such atoms are electrically inactive.

However, at a certain range of temperatures, such as low as about 350 and up to about 500 degrees centigrade, the oxygen interstitials may start to precipitate in clusters that electrically activate and generate (n-type) donor carriers which may combine to electrically neutralize a corresponding number of p-type dopant carriers present in the silicon material. Effects of such neutralization on overall resistivity of a substrate may depend on relative concentration of the generated (n-type) donors to the concentration of the (p-type) dopants. In particular, considering a case of a non-HR-Si substrate made from a low-oxygen silicon material, because the concentration of the dopants may be orders of magnitude greater than the concentration of the generated donors, then influence of the electrical neutralization on overall (low) resistivity of the substrate may be negligeable and therefore undetectable.

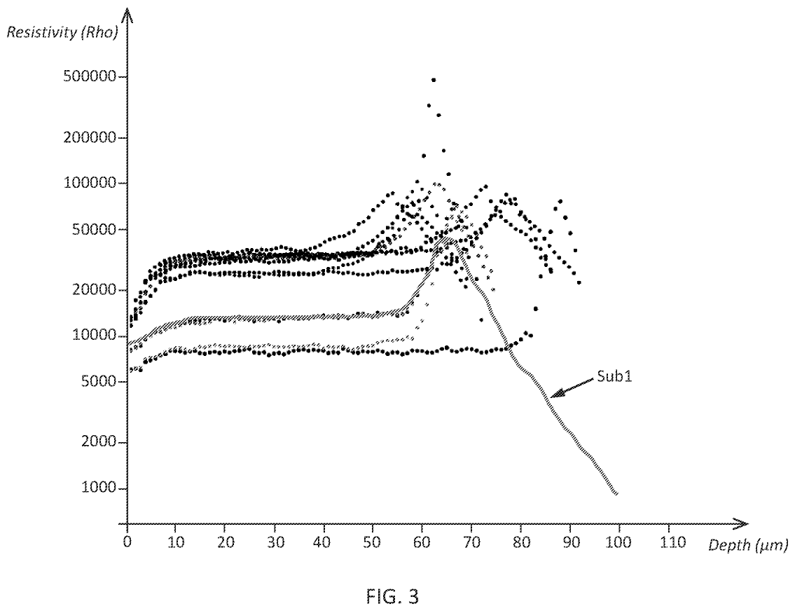

On the other hand, considering a case of a HR-Si substrate that according to the present disclosure includes low-oxygen silicon material, because the concentration of the dopants may be a same order of magnitude (or smaller) than the concentration of the generated donors, then, as shown in the graphs of FIG. 3, influence of the electrical neutralization on overall (low) resistivity of the substrate may be noticeable and therefore (clearly) detectable.

FIG. 3 shows (several) graphs representing effects of donor carriers generated by electrically activated oxygen atoms on the resistivity of HR-Si substrates made from low-oxygen silicon material. As described above, electrical activation of the oxygen atoms in the silicon material may be triggered by subjecting a HR-Si substrate to a temperature in a range from about 350 to 400 degrees centigrade. In particular, it is noted that HR-Si substrates may be subjected to such temperature range during a packaging processing step that follows fabrication of SOI circuits/devices on corresponding HR-SOI wafers (e.g., 100A/B of FIG. 1A/1B).

With continued reference to FIG. 3, the various graphs shown may represent resistivity of various types of HR-Si substrates that may have different nominal resistivity values (e.g., per graphs of FIG. 2) and/or subjected to oxygen atoms'electrical activation temperatures for different times. A person skilled in the art would notice that the shown graphs include similar profiles, including a first substantially flat portion, a ramp-up portion, and a ramp-down portion. For example, considering the resistivity graph for a HR-Si substrate labeled in FIG. 3 as Sub1, the substantially flat portion is at a depth range of 0 -60 μm, the ramp-up portion is at a depth range of 60-70 μm, and a ramp-down portion is at a depth range greater than 70 μm. In particular, the resistivity of the HR-Si substrate, Sub 1, during the ramp-down portion of the graph decreases to values that are below the 1000 ohm·cm. In other words, the resistivity reaches low values that may be unacceptable when considering RF performance capabilities provided by the substrate.

With further reference FIG. 3, for example, at the depth range of 0 -60 μm, a number of oxygen atoms that are electrically activated to generate donor carriers may not be sufficient to influence resistivity of the HR-Si substrate, Sub1; at the depth range of 60-70 μm, the number of oxygen atoms that are electrically activated to generate donor carriers may be sufficient to influence resistivity of the HR-Si substrate, Sub1, such number being smaller (and increasing with depth) than a number of dopant carriers up to the peak resistivity at about 70 μm, where the number of generated donor carriers is equal to the number of dopant carriers; and at the depth range greater than about 70 μm, the number of oxygen atoms that are electrically activated to generate donor carriers may be sufficient to influence resistivity of the HR-Si substrate, Sub1, such number being greater (and increasing with depth) than a number of dopant carriers. In other words, past the peak resistivity at about 70 μm, the HR-Si substrate changes type from p-type to n-type.

It is noted that although the resistivity graphs shown in FIG. 3 depend on concentration profiles of oxygen atoms (e.g., Oi) in the silicon material, such profiles may not necessarily be same, nor include slopes (gradients). Although slopes may naturally occur due to inherent material (out-) diffusion effects, constant concentration profiles of the oxygen atoms in a low-oxygen concentration silicon material may result in same detectable changes in resistivities of corresponding HR-Si substrates. As shown in the graphs of FIG. 3, such changes in resistivity may cause resistivity to fall below the plateau area down to about 1000 ohm·cm or less.

Having realized of the above-described effects contributable to the presence of oxygen atoms in HR-Si substrates in the sense of the present disclosure, applicant has devised process steps that control electrical activation of the oxygen atoms to maintain desired/nominal resistivity profiles of the HR-Si substrates (e.g., per FIG. 2). It is noted that although high-temperature (e.g., about 1000 degrees centigrade or higher) corrective steps may be devised in order to restore desired/nominal resistivity profiles subsequent to activation of the oxygen atoms (e.g., via a low temperature process step in a range of about 350-400 degrees centigrade), such high temperature corrective steps may not be possible after introduction of metal layers as performed during a back end of line (BEOL) portion of a semiconductor fabrication (FAB). It follows that teaching according to the present disclosure remove/avoid any post fabrication (FAB) process steps, including annealing steps, that use temperatures in a range of about 350-400 degrees centigrade.

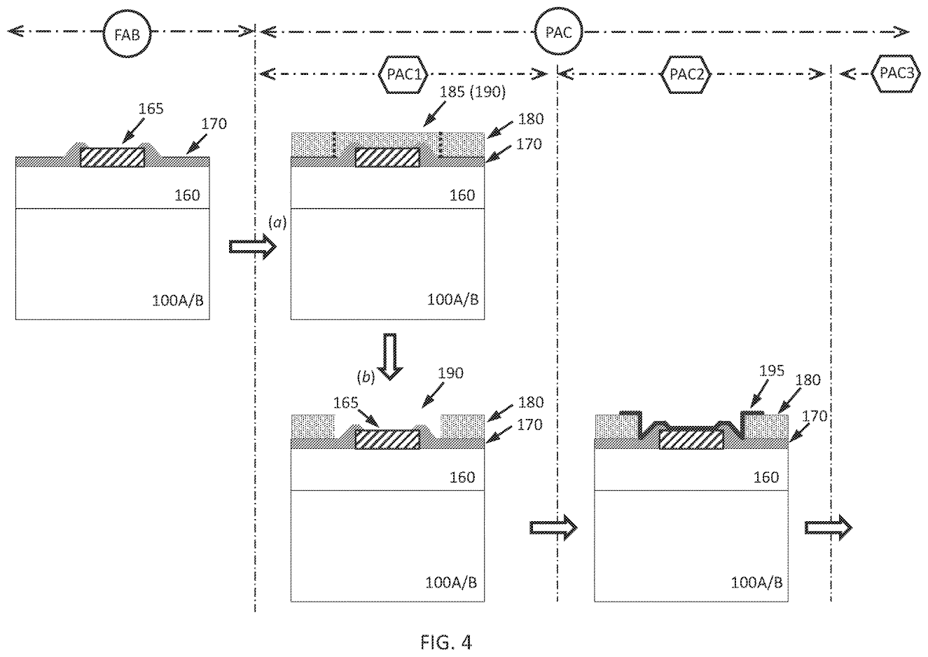

FIG. 4 shows various processing steps of a SOI substrate (100A/B) according to an embodiment of the present disclosure. Such steps include steps that follow the semiconductor fabrication (FAB) and are known to be part of packaging (PAC) which may encompass testing, scanning, packaging and/or dicing steps as known in the art. However, differently from known in the art packaging (PAC) process steps, the processing steps shown in FIG. 4 do not include processing at temperatures (i.e., about 350-400 degrees centigrade) that may electrically activate oxygen atoms.

As shown in FIG. 4, the semiconductor fabrication (FAB) produces a composite substrate (100A/B, 160, 165, 170) that includes a circuit (160, e.g., layer, semiconductor devices, metal and/or insulating layers) fabricated atop the HR-SOI wafer (100A/B of FIG. 1A/1B). A top surface of the circuit (160) may be covered with an insulating passivation layer (170, e.g., oxide and nitride) while leaving a metal pad (165, e.g., input/output pad) of the circuit (160) exposed. As shown in FIG. 4, entirety of the lateral edges/surfaces of the metal pad (160) may contact the passivation layer (170). In other words, the passivation layer (170) may fully surround the metal pad (160) including covering of the top surface edges of the metal pad (160). Accordingly, the composite substrate (110A/B, 160, 165, 170) produced by FAB is provided to packaging, PAC.

With continued reference to FIG. 4, during a processing step, PAC1, of the PAC, according to the present disclosure, a polyimide material (180, e.g., compound) is coated (step a) atop the (full surface of the) composite substrate (110A/B, 160, 165, 170) and then a portion (185) thereof is exposed for removal (e.g., etching out). Such step may be considered as a low temperature step with a high peak temperature (e.g., smaller than 110 degrees centigrade) that is lower than the electrical activation temperature range (e.g., about 350-400 degrees centigrade) of oxygen atoms in the HR-SOI wafer (100A/B). Therefore a (nominal) resistivity profile of a corresponding HR-Si substrate (e.g., 150 of FIG. 1A/1B) is maintained. After exposure, the portion (185) is removed to form an opening (190) which exposes the top surface of the metal pad (165) and surrounding passivation layer (170).

In the next step (b) of the processing step, PAC1, a remaining portion of the polyimide material (180) is cured (e.g., annealed) at a (peak) temperature in range of 200-250 degrees centigrade instead of a typical range of 350-400 degrees centigrade. Since such low temperature curing is in a range that is outside the electrical activation temperature range of oxygen atoms in the HR-SOI wafer (100A/B), a (nominal) resistivity profile of a corresponding HR-Si substrate (e.g., 150 of FIG. 1A/1B) is maintained. Accordingly, as shown in FIG. 4, the cured polyimide material (180) surrounds the opening (190) that exposes the top surface of the metal pad (165) and surrounding passivation layer (170). In turn, as shown in FIG. 4, this allows during a next processing step, PAC2, of the PAC, to deposit a conductive material (195, e.g., titanium and copper, seed layer deposition) over the exposed top surface of the metal pad (165) and surrounding passivation layer (170).

It is noted that the processing step, PAC1, of FIG. 4 may be likened to a polyimidization step as known in the art but modified not to use a (peak) temperature in a range that may electrically activate oxygen atoms in the HR-SOI wafer (100A/B). Furthermore, the processing step, PAC2, may be likened to a seed layer deposition step followed by an etching step that are known in the art, steps that may be considered as precursors to a plating (e.g., Cu plating) step as known in the art. In other words, the processing step PAC1 (and PAC2) according to the present disclosure may be compatible with any standard downstream processing step (e.g., PAC3) known in the art of IC packaging. These include processing steps at (peak) temperatures that are lower than about 250 degrees centigrade for IC packaging that support any of LF solder bump flow, Cu pillar bump flow, or WLCSP ball drop flow.

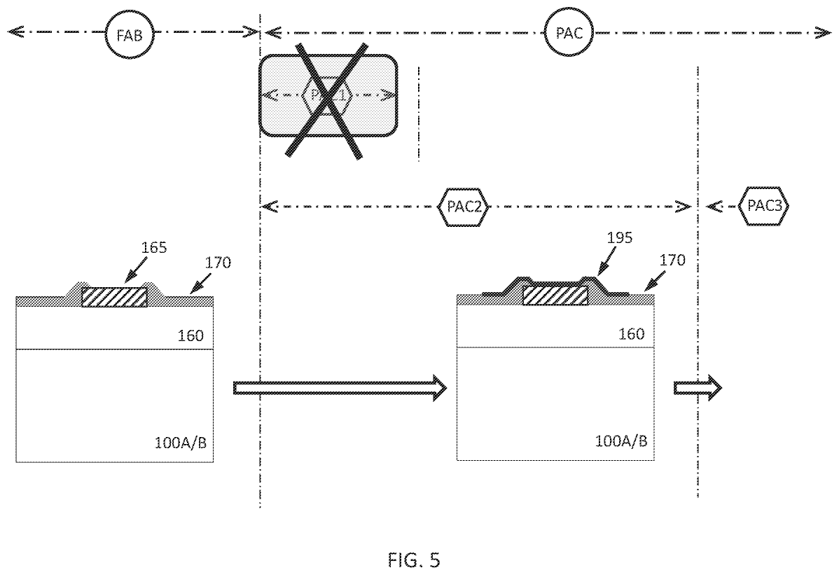

FIG. 5 shows various processing steps of a SOI substrate (100A/B) according to an embodiment of the present disclosure. Such steps differ with respect to steps described above with reference to FIG. 4 by their lack of the processing step PAC1, also known as the polyimidization step. In other words, the packaging, PAC, process steps according to FIG. 5 are devoid of the polyimidization step, PAC1, that typically includes processing at temperatures in a range of about 350-400 degrees centigrade that may electrically activate oxygen atoms. Accordingly, as shown in FIG. 5, the composite substrate (100A/B, 160, 165, 170) produced during the semiconductor fabrication, FAB, is subjected to the seed layer deposition step, PAC2, that directly deposits (and etches) a metal layer (e.g., titanium and copper) atop the exposed surface of the metal pad (165) and surrounding passivation layer (170). Following (downstream) steps (e.g., PAC3) at (peak) temperatures that are lower than about 250 degrees centigrade as known in the art for packaging integrated circuits may be executed, including processing steps for IC packaging that support any of LF solder bump flow, Cu pillar bump flow, or WLCSP ball drop flow.

With reference back to FIG. 4 and FIG. 5, because the described processing steps do not use temperatures higher than about 250 degrees centigrade, resistivity of the SOI substrate (100A/B) is maintained. However, as shown in FIGS. 4 and 5, different layered structures are generated. In particular, the processing steps according to FIG. 4 generate a layered structure (195, 180, 170) that includes, at least in a region close to, but not immediately surrounding, the metal pad (160), in order, a metal (195, e.g., titanium and copper), a cured polyimide (180), and an insulator (170, passivation layer) overlying the circuit (160), wherein the layers (195), (180) and (170) are in direct contact. On the other hand, in a region that is immediately surrounding the metal pad (160) and adjacent the layered structure (195, 180, 170), a different layered structure (195, 170) that includes, in order, the metal (195, e.g., titanium and copper), and the insulator (170) overlying the circuit (160) is formed.

Furthermore, the processing steps according to FIG. 5 do not generate that layered structure (195, 180, 170), since as shown in FIG. 5, a corresponding layered structure (195, 170) in a region close to the metal pad (160) is a same layered structure (195, 170) that surrounds the metal pad (160), and includes, in order, the metal (195, e.g., titanium and copper), and the insulator (170) overlying the circuit (160), wherein the layers (195) and (170) are in direct contact.

Teachings according to the present disclosure eliminate or modify any post-fabrication (FAB) processing steps that include temperatures in a range of about 350-400 degrees centigrade. In particular, a polyimidization processing step as known in the art is modified for execution at a (peak) temperature that is in a range of about 200-250 degrees centigrade. Accordingly, the present teachings use a certain class of polyimide that in combination with a precursor (e.g., precursor polyamic acid, PAA, comprising an amine unit and an acid unit) may be adequately cured/annealed at the relatively low (peak) temperature range of about 200-250 degrees centigrade. In some embodiments according to the present disclosure, decreasing of the acidity of the amine unit of the precursor or increasing the acidity of the acid unit of the precursor, may be a sufficient condition for curing/annealing in said temperature range. According to other embodiments, a catalyst may be used instead.

The term “MOSFET”, as used in this disclosure, includes any field effect transistor (FET) having an insulated gate whose voltage determines the conductivity of the transistor, and encompasses insulated gates having a metal or metal-like, insulator, and/or semiconductor structure. The terms “metal” or “metal-like” include at least one electrically conductive material (such as aluminum, copper, or other metal, or highly doped polysilicon, graphene, or other electrical conductor), “insulator” includes at least one insulating material (such as silicon oxide or other dielectric material), and “semiconductor” includes at least one semiconductor material.

As used in this disclosure, the term “radio frequency” (RF) refers to a rate of oscillation in the range of about 3 kHz to about 300 GHz. This term also includes the frequencies used in wireless communication systems. An RF frequency may be the frequency of an electromagnetic wave or of an alternating voltage or current in a circuit.

Various embodiments of the invention can be implemented to meet a wide variety of specifications. Unless otherwise noted above, selection of suitable component values is a matter of design choice. Various embodiments of the invention may be implemented in any suitable integrated circuit (IC) technology (including but not limited to MOSFET structures), or in hybrid or discrete circuit forms. Integrated circuit embodiments may be fabricated using any suitable substrates and processes, including but not limited to standard bulk silicon, high-resistivity bulk CMOS, silicon-on-insulator (SOI), trap rich SOI, trap rich HR-SOI, RF SOI, and silicon-on-sapphire (SOS). Unless otherwise noted above, embodiments of the invention may be implemented in other transistor technologies such as bipolar, BiCMOS, LDMOS, BCD, GaAs HBT, GaN HEMT, GaAs pHEMT, and MESFET technologies. However, embodiments of the invention are particularly useful when fabricated using an SOI or SOS based process, or when fabricated with processes having similar characteristics. Fabrication in CMOS using SOI or SOS processes enables circuits with low power consumption, the ability to withstand high power signals during operation due to FET stacking, good linearity, and high frequency operation (i.e., radio frequencies up to and exceeding 300 GHz). Monolithic IC implementation is particularly useful since parasitic capacitances generally can be kept low (or at a minimum, kept uniform across all units, permitting them to be compensated) by careful design.

Voltage levels may be adjusted, and/or voltage and/or logic signal polarities reversed, depending on a particular specification and/or implementing technology (e.g., NMOS, PMOS, or CMOS, and enhancement mode or depletion mode transistor devices). Component voltage, current, and power handling capabilities may be adapted as needed, for example, by adjusting device sizes, serially “stacking” components (particularly FETs) to withstand greater voltages, and/or using multiple components in parallel to handle greater currents. Additional circuit components may be added to enhance the capabilities of the disclosed circuits and/or to provide additional functionality without significantly altering the functionality of the disclosed circuits.

Circuits and devices in accordance with the present invention may be used alone or in combination with other components, circuits, and devices. Embodiments of the present invention may be fabricated as integrated circuits (ICs), which may be encased in IC packages and/or in modules for ease of handling, manufacture, and/or improved performance. In particular, IC embodiments of this invention are often used in modules in which one or more of such ICs are combined with other circuit blocks (e.g., filters, amplifiers, passive components, and possibly additional ICs) into one package. The ICs and/or modules are then typically combined with other components, often on a printed circuit board, to form part of an end product such as a cellular telephone, laptop computer, or electronic tablet, or to form a higher-level module which may be used in a wide variety of products, such as vehicles, test equipment, medical devices, etc. Through various configurations of modules and assemblies, such ICs typically enable a mode of communication, often wireless communication.

A number of embodiments of the invention have been described. It is to be understood that various modifications may be made without departing from the spirit and scope of the invention. For example, some of the steps described above may be order independent, and thus can be performed in an order different from that described. Further, some of the steps described above may be optional. Various activities described with respect to the methods identified above can be executed in repetitive, serial, and/or parallel fashion.

It is to be understood that the foregoing description is intended to illustrate and not to limit the scope of the invention, which is defined by the scope of the following claims, and that other embodiments are within the scope of the claims. In particular, the scope of the invention includes any and all feasible combinations of one or more of the processes, machines, manufactures, or compositions of matter set forth in the claims below. (Note that the parenthetical labels for claim elements are for ease of referring to such elements, and do not in themselves indicate a particular required ordering or enumeration of elements; further, such labels may be reused in dependent claims as references to additional elements without being regarded as starting a conflicting labeling sequence).

1. A method for processing a high resistivity silicon-on-insulator (HR-SOI) wafer, the method comprising:
processing, via semiconductor fabrication steps, the HR-SOI wafer, thereby producing:
a circuit layer atop a silicon-on-insulator (SOI) layer of the HR-SOI wafer; and
a passivation layer atop the circuit layer including an opening that exposes a metal pad in contact with the circuit layer;
overlying a polyimide atop the passivation layer and the metal pad; and
curing the polyimide at a peak temperature that is below about 250 degrees centigrade thereby maintaining a nominal high resistivity of the HR-SOI wafer.

2. The method according to claim 1, wherein:
the nominal high resistivity of the HR-SOI wafer is provided by a high resistivity silicon (HR-Si) substrate of the HR-SOI wafer, and
the nominal high resistivity is greater than about 1000 ohm·cm.

3.-4. (canceled)

5. The method according to claim 2, wherein:
the HR-Si substrate includes a dopant concentration that is in a range from about 10¹²×cm⁻³ to about 10¹³×cm⁻³.

6. (canceled)

7. The method according to claim 2, wherein:
the HR-Si substrate includes a silicon material having a concentration of oxygen atoms that is in a range from about 10¹¹×cm⁻³ to about 10¹⁵×cm⁻³.

8. The method according to claim 1, wherein:
the HR-SOI wafer includes a buried oxide (BOX) layer immediately below the SOI layer, and
the HR-SOI wafer includes a trap rich layer immediately below the BOX layer.

9. The method according to claim 1, further comprising:
prior to the curing, etching away a portion of the polyimide overlying the metal pad thereby exposing the metal pad and a surrounding region of the passivation layer.

10. (canceled)

11. A method for processing a high resistivity silicon-on-insulator (HR-SOI) wafer, the method comprising:
processing, via semiconductor fabrication steps, the HR-SOI wafer, thereby producing a circuit layer comprising integrated circuits; and
processing, via integrated circuit packaging steps, the HR-SOI wafer, thereby producing packaged integrated circuits,
wherein a peak temperature during the integrated circuit packaging steps is below about 250 degrees centigrade thereby maintaining a nominal high resistivity of the HR-SOI wafer.

12. The method according to claim 11, wherein:
the integrated circuit packaging steps include a polyimidization step at a peak temperature that is below the about 250 degrees centigrade.

13. The method according to claim 11, wherein:
the integrated circuit packaging steps are devoid of a polyimidization step.

14. The method according to claim 11, wherein: (HR-Si) substrate of the HR-SOI wafer, and the nominal high resistivity is greater than about 1000 ohm·cm.

15.-16. (cancelled)

17. The method according to claim 14, wherein:
the HR-Si substrate includes a dopant concentration that is in a range from about 10¹²×cm⁻³ to about 10¹³×cm⁻³.

18. (canceled)

19. The method according to claim 14, wherein:
the HR-Si substrate includes a silicon material having a concentration of oxygen atoms that is in a range from about 10¹¹×cm⁻³ to about 10¹⁵×cm⁻³.

20. The method according to claim 11, wherein:
the HR-SOI wafer includes a buried oxide (BOX) layer immediately below the SOI layer, and
the HR-SOI wafer includes a trap rich layer immediately below the BOX layer.

21.-29. (canceled)

30. A method for processing a high resistivity silicon-on-insulator (HR-SOI) wafer, the method comprising:
processing, via semiconductor fabrication steps, the HR-SOI wafer, thereby producing:
a circuit layer atop a silicon-on-insulator (SOI) layer of the HR-SOI wafer; and
a passivation layer atop the circuit layer including an opening that exposes a metal pad in contact with the circuit layer;
overlying a polyimide atop the passivation layer and the metal pad; and
curing the polyimide at a peak temperature selected such that a nominal high resistivity of the HR-SOI wafer is maintained.

31. The method according to claim 30, wherein:
the nominal high resistivity of the HR-SOI wafer is provided by a high resistivity silicon (HR-Si) substrate of the HR-SOI wafer, and
the nominal high resistivity is greater than about 1000 ohm·cm.

32.-33. (canceled)

34. The method according to claim 30, wherein:
the HR-Si substrate includes a dopant concentration that is in a range from about 10¹²×cm⁻³ to about 10¹³×cm⁻³.

35. (canceled)

36. The method according to claim 30, wherein:
the HR-Si substrate includes a silicon material having a concentration of oxygen atoms that is in a range from about 10¹¹×cm⁻³ to about 10¹⁵×cm⁻³.

37. The method according to claim 30, wherein:
the HR-SOI wafer includes a buried oxide (BOX) layer immediately below the SOI layer, and
the HR-SOI wafer includes a trap rich layer immediately below the BOX layer.

38. The method according to claim 30, further comprising:
prior to the curing, etching away a portion of the polyimide overlying the metal pad thereby exposing the metal pad and a surrounding region of the passivation layer. Page 7

39. The method according to claim 37, further comprising:
depositing a conductive layer atop the metal pad and the surrounding region of the passivation layer, the conductive layer used as a seed layer for subsequent processing of the HR-SOI wafer.
